(19) United States
(12) Patent Application Publication
(10) Pub. No.: US 2026/0013051 A1
(43) Pub. Date: Jan. 8, 2026

(54) ELECTRONIC CONTROL BOX WITH VARIABLE HEIGHT

(71) Applicant: Danfoss Power Electronics A/S, Gråsten (DK)

(72) Inventor: Carsten Marek, Sønderborg (DK)

(21) Appl. No.: 19/256,257

(22) Filed: Jul. 1, 2025

(30) Foreign Application Priority Data
Jul. 4, 2024 (DE) 102024119035.3

(51) Int. Cl. H05K 5/00; H05K 5/02

(52) U.S. Cl. CPC H05K 5/0018; H05K 5/0047; H05K 5/0069; H05K 5/0247

(57) ABSTRACT

The disclosure relates to an electronic control box (1) that includes a housing (2) with at least a first part (3) and a second part (4). The electronic control box (1) further includes an electronic controller unit (5) and at least one human control interface (6). The electronic controller unit (5) is mounted in the first part (3) of the housing (2) and the human control interface (6) is arranged in at least one section of the second part (4) of the housing (2). At least one rigid information transmitting device (7, 8) is used that is designed and arranged to transmit an optical (8) and/or an electrical (7) signal between the electronic controller unit (5) and the human control interface (6). The at least one rigid information transmitting device (7, 8) is placed between the electronic controller unit (5) and the human control interface (6), and is separate from the electronic controller unit (5) and the human control interface (6).

### CROSS-REFERENCE TO RELATED APPLICATIONS

This application claims foreign priority benefits under 35 U.S.C. § 119 to German Patent Application No. 102024119035.3 filed on Jul. 4, 2024, the content of which is hereby incorporated by reference in its entirety.

### TECHNICAL FIELD

The invention relates to an electronic control box comprising a housing, an electronic controller unit and at least a human control interface. The invention further relates to an assembly kit, comprising at least one electronic control box of the afore mentioned type. Further, the invention relates to a method of arranging an electronic controller unit and a human control interface at a different distance.

### BACKGROUND

Electronic control boxes are used in a wide variety of technical fields. They are both used for stationary and mobile applications. The usual common feature is that they comprise a housing, into which an electronic controller unit is placed, for example a printed circuit board controller. The controller unit may be programmable or not. Furthermore, since the controller unit has to be monitored and/or controlled by an operator, the electronic control box typically comprises a human control interface (control panel), on which information may be displayed, and into which commands may be entered.

Due to the widespread use of such electronic control units, it is no surprise that a large number of standard components are available in the market. In particular, the user (either end-user or manufacturer of certain products) may choose from a wide variety of components that are readily available on the market. This particularly relates to electronic controller units for performing various tasks, as well as for human control interfaces.

While the so-to-say technical aspect is widely standardised, certain problem persists with the housing, into which such standard components are to be accommodated. Such housings are regularly unique to the particular type of serial product, they are used for. The large number of variations of housings are no surprise since design considerations, available mounting volume, side-effect considerations involved with the function of the machinery and so on have to be considered and have an influence on the design and dimension of the housing. Consequently, the dimensions of the housing are chosen individually, and the resulting housings have to be produced accordingly individually.

A problem occurs particularly, if the height of the housing of an electronic control box has to be varied, which typically results in a different distance (height difference; offset) of the electronic controller unit and the human control interface of the electronic control box.

Again, due to the widespread use of electronic control boxes, some standard solutions are known in the prior art.

The most straightforward solution is of course to individually adapt the electronic controller unit and/or the human control interface, so that an appropriate distance between them is reached and/or that electric connectors do protrude appropriately from the electronic controller unit and/or the human control interface. However, this requires at least an adaption of the design of the electronic controller unit and/or the human control interface, which is costly, requires additional storage of prefabricated parts (and later on spare parts for maintenance) and generally contradicts the approach of standardisation of components.

The other usually used approach is the idea to use flexible cable connections between the electronic controller unit and the human control interface. However, the associated wiring is somewhat cumbersome and requires sometimes quite tricky assembly steps. This includes the case, where the wiring between the electronic controller unit and the human control interface is made using plug-in connectors. Furthermore, elastic electric cables are somewhat prone to a certain movement when vibrations occur-something that is standard both in stationary and mobile applications, and which can result in a break of electric cables over time.

It is therefore obvious that there is a need in the technical field to simplify the arrangement of standard components, in particular of an electronic controller unit and a human control interface of an electronic control box at different distances, while using standard components.

### SUMMARY

It is therefore an object of the invention to suggest an electronic box, comprising a housing with at least a first part and a second part, an electronic controller unit and at least a human control interface that is improved over electronic control boxes of this type, as they are known in the state-of-the-art.

It is another object of the invention to suggest an assembly kit comprising at least one electronic control box that is improved over assembly kits of this type as that they are known in the state-of-the-art.

It is yet another object of the invention to propose a method of arranging an electronic controller unit and human control interface at a different distance that is improved over such methods as they are known in the state-of-the-art.

An electronic control box according to claim 1 solves this object. Further, an assembly kit according to claim 8 solves this object. Even further, a method of arranging an electronic controller unit and a human control interface at different distances according to claim 9 solves this object.

It is suggested to design an electronic control box that comprises a housing with a first part and a second part, and that further comprises an electronic controller unit and at least one human control interface, wherein the electronic controller unit is mounted in the first part of the housing and the human control interface is arranged in at least one section of the second part of the housing, in a way that it further comprises at least one rigid information transmitting device that is designed and arranged to transmit a signal between the electronic controller unit and the human control interface and that is placed between the electronic controller unit and the human control interface, and that is separate from the electronic controller unit and the human control interface. Preferably, the signal that is transmitted by the at least one rigid information transmitting device is an optical and/or an electrical signal.

The housing typically comprises two parts, that can preferably be reversibly attached to each other. This way, the housing can be opened and closed. The reopening might be advantageous for maintenance or repair purposes. However, it is also possible that the housing can only be closed once (for example by using some barbed hook or like) so that it cannot be easily opened, in particular in a way that it cannot be opened without any damage or even destruction of the housing. This might be advantageous for safety relevant systems, so that a manipulation of the electronic control box can be hindered, or its probability can be at least reduced.

According to the present suggestion, the electronic controller unit is mounted in the first part of the housing. This does not necessarily exclude the possibility that at least parts of the electronic controller unit may form a part of the housing surface, or may even protrude from the surface of the housing. An example for this would be a plug/socket that is soldered to the electronic controller unit, and that is fit into a recess that is provided for this plug/socket in the respective section of the housing (first part of the housing). The electronic controller unit may be attached to the first part of the housing in any usual way, for example using screws, barbed hooks or the like.

The human control interface is arranged in at least one section of the second part of the housing. Typically, the human control interface (or parts thereof) do forms an outer surface of the housing, or even protrude from the housing. This is due to the fact that typically at least the surface of the human control interface has to be visible (for providing some kind of a visible display to the user) and/or to be reachable from the outside (so that the user can make custom inputs). This is well known the state-of-the-art.

At least one rigid information transmitting device is provided that is designed and arranged to transmit a signal, in particular an optical and/or an electrical signal, between the electronic controller unit and the human control interface.

It is to be noted that depending on the first part and/or the second part of the housing that is chosen for the concrete electronic control box (even the use of a third or more parts of the housing may be envisioned), the distance between the electronic controller unit and the at least one human control interface typically does vary. Therefore, this variation in distance between the two parts (human control interface and electronic controller unit) has to be bridged. However, not only a mechanical spacing has to be accounted for, but also—depending on the actual situation—an electric and/or optical communication between the electronic controller unit and the human control interface has to be provided.

For this reason, a rigid information transmitting device is placed between the electronic controller unit and the human control interface. Further, the rigid information transmitting device is designed to be a separate part, being separate from the electronic controller unit and from the human control interface. This way, for essentially all realistic distances between the electronic controller unit and the human control interface, identical electronic controller units and identical human control interfaces may be used. The distance is bridged by the one or several rigid information transmitting devices. Therefore, apart from the housing, only the rigid information transmitting devices have to be adapted. In particular, their length has to be adapted. Since typically certain discrete distances between the electronic controller unit at the human control interface are realised, it is sufficient to have an appropriate (limited) number of accordingly dimensioned (in particular length dimension) rigid information transmitting devices on shelf, where the correct one is picked and placed between the electronic controller unit and the human control interface.

Thanks to the rigid design of the rigid information transmitting device, a shortening of the lifetime due to cable breaks caused by a bending/vibration of the electric conductors (and/or optical conductors) between the electronic controller unit and the human control interface can be advantageously reduced or even essentially omitted. Further, thanks to the rigid design of the rigid information transmitting device, the rigid information transmitting device may serve as a mechanical stabilisation or even as a mechanical support of the various pieces, in particular of the electronic controller unit with respect to the human control interface. Again, this may increase the reliability of the arrangement.

While essentially all types of signals may be transmitted by an accordingly designed rigid information transmitting device (for example sound or the like), typically optical and/or electrical signals have to be transmitted; therefore, it is preferred if the at least one rigid information transmitting device is designed and arranged in a way to transmit an optical and/or an electrical signal.

It is to be noted that a comparatively small number of rigid information transmitting devices (in particular a single one) simplifies the assembly of the electronic control box. On the other hand, a large number of rigid information transmitting devices may improve the mechanical stability of the electronic control box arrangement. Typically, according to one usual approach, a single rigid information transmitting device is chosen to simplify assembly of the electronic control box. Then, an appropriate mechanical stability usually has to be provided by additional means, for example by the housing/parts of the housing. According to another typical approach, a comparatively small number of rigid information transmitting devices is used, like two, three or four rigid information transmitting devices. This may serve as a good compromise between a comparatively easy assembly of the electronic control box, combined with a particularly high mechanical stability of the arrangement.

The electronic control box may be used for a motor drive/motor drive arrangement. Even further, the electronic control box may be located in a motor drive (arrangement) and/or may be a part of a motor drive (arrangement). The motor drive/motor drive arrangement may particularly include all electric and electronic units that are necessary to control the actuation of an (electric) motor. Therefore, the motor drive (arrangement) does not necessarily have to include a power source (for example a battery, an accumulator or the like, but it certainly may comprise such a power source). In particular, the motor drive (arrangement) might comprise a PWM unit (pulse width modulation unit), power electronics, rectifiers, AC converters and the like.

It is suggested to design the electronic control box in a way that at least one of the rigid information transmitting devices comprising at least two, preferably a plurality of conduits. It is possible, that at least in part, the plurality of conduits are designed and arranged for the same signal type. Additionally or alternatively, they may also be designed, at least in part, for different signal types. Just to give an example: when it comes to electrical signals, usually at least two conduits/conductors have to be provided, to close the electric circuitry. If a larger number of electrical lines is provided, a larger number of signals can be transmitted, in particular without relying on bus systems. However, even if a bus system is used, usually at least four electric conductors are used, namely two for electrical supply purposes and another two for information transmittal purposes. Additionally or alternatively, one or a plurality of optical conductors may be used, so as to transmit one or several optical signals. As an example: light might be generated by one or a plurality of LEDs (or different light sources) that are connected/soldered to the electronic controller unit and that emit light in different colours (for example red, green, blue, yellow, white, or any other colour). In particular, it should be pointed out that even a single LED might emit different colours, if so called multi-colour LEDs are used. The optical light transmitting medium (some kind of a light conduit, light guiding tube or fibre, or the like might be used) is then advantageously transmitting the thus generated light to a dedicated outlet at the human control interface. This way, light from different light sources is advantageously not mixed, so that a misinterpretation of the optical signal may be avoided. Furthermore, even if such a mixture of different light sources is not a problem (for whatever reason, for example since only one light source is present), the light intensity at the human control interface can typically be increased, which is certainly advantageous. It is to be noted that the rigid information transmitting device may be designed as a common block. For example, a common block of four electric conduits and three optical conduits might be envisioned. This way, by using a single assembly process, a plurality of signals can be transmitted, even in case of signals that are of a different physical nature.

Furthermore, it is suggested to design the electronic control box in a way that at least one of the rigid information transmitting devices is designed and arranged as an electrical connector and/or as an optical conduit device. These are the most usual signals that have to be transmitted. Therefore, the electronic control box can be particularly advantageous.

Even further, it is suggested to design the electronic control box in a way that (at least one of) the rigid information transmitting device is designed and arranged as a plug-in connector device, preferably at least in part and/or at least on one of its sides. This way, the assembly of the arrangement can be further simplified. In particular, standard type plug-in connector devices can be used. Just to name an example: D-sub connectors, connector strip devices/pinstripe devices or the like might be used for this purpose. It is to be noted that plug-in connector devices are usually particularly advantageous in connection with electrical signals.

Yet further it is suggested to design the electronic control box in a way that the first part of the housing comprises a bottom surface wall and/or that the second part of the housing comprises a top surface wall and/or in a way that at least one of the parts of the housing comprises a side wall and/or in a way that the housing comprises a third part that is designed and arranged as a side wall. Additionally or alternatively, the electronic control box may be designed in a way that the distance between the electronic controller unit in the at least one human control interface can be varied, preferably in steps. It is to be noted that one part of the housing might show a trough-shaped design, where the sidewalls may protrude from the bottom wall (or possibly top surface wall) in a more or less perpendicular direction. This design is standard in the state-of-the-art for well known reasons. Then, a variation of the height of the housing (and therefore typically of the distance between the human controller interface and the electronic controller unit may be varied by providing higher or lower sidewalls. However, it is also possible that a third part (or even more additional parts) is provided that serves as a sidewall, or that extends the length of the sidewalls. Such a third part might be of an essentially collar-like design, where the dimensions and cross sections may be chosen to be consistent to the remaining parts of the housing/the remaining sidewalls of the housing. If a height variation is foreseen in steps, the number of parts of the housing (first part, second part and/or possibly third or even further parts) might be reduced. Consequently, typically the amount of differently sized rigid information transmitting devices may be reduced as well. It is to be noted, that the distance between the electronic controller unit and the at least one human control interface may be varied by different means as well, for example by providing protruding support webs or the like.

Yet further, it is suggested to design the electronic control box in a way that the electronic controller unit comprises a plurality of sub-units and/or in that the electronic controller unit is designed, at least in part, as a printed circuit board. This way, the flexibility of the electronic control box can be enhanced. Furthermore, the design of the components of the electronic control box may be more similar, or even be identical, to already presently used parts. This way, the acceptance of the system may be enhanced.

Yet further, it is suggested to design the electronic control box in a way that at least one human control interface is taken from the group, comprising optical indicators, buttons, touch areas, electronic displays, light-emitting areas, control panels and the like. This way, again, the design and functionality of the at least one human control interface may resemble (or be essentially identical) to known human control interfaces, so that the acceptance of the electronic control box can be increased even further.

Furthermore, an assembly kit is suggested that comprises at least one electronic control box, wherein the at least one electronic control box is designed and arranged according to the present disclosure. At least two housing parts will result in a different distance between the electronic controller unit and the human control interface (where in this context, the two housing parts usually do relate to the same type of housing part, for example to a differently dimensioned first part of the housing). Preferably the at least two housing parts yield a different height of the side walls of the housing. At least two rigid information transmitting devices are provided, wherein the at least two rigid information transmitting devices show a different length. The lengths of the rigid information transmitting devices correspond to the different distances between the electronic controller unit and the human control interface (usually caused by the at least two different housing parts of the same type). In this way, a plurality of different electronic control boxes can be easily provided by using standard components for the most expensive and delicately designed parts, namely for the electronic controller unit and/or the human control interface. The remaining parts, however, in particular respective parts of the housing and differently dimensioned rigid information transmitting devices are comparatively easy to be adopted. Therefore, the cost effectiveness may be increased. Further, fewer components have to be stored on shelf for manufacture (and/or for repair purposes), so space and logistics costs can also be reduced.

Yet further, a motor drive/motor drive arrangement is suggested that comprises an electronic control box according to the present disclosure. Additionally or alternatively, an assembly kit for a motor drive/motor drive arrangement is suggested that comprises an assembly kit with at least one electronic control box according to the present disclosure.

Even further, a method of arranging an electronic controller unit and a human control interface at a different distance is suggested, wherein the signal connection between the electronic controller unit and the human control interface is effectuated by at least one rigid information transmitting device. Preferably, this difference in distance may occur in connection with a (differently dimensioned) housing. Additionally or alternatively, it is preferred if the signal connection relates to an electrical signal connection and/or to an optical signal connection. Using this proposal, the already described features and advantages can be realised, at least in analogy.

Furthermore, the method may be modified in the sense of the present disclosure, at least in analogy. This may result in appropriate characteristics and advantages, as already discussed, at least in analogy.

In particular, the method may be employed in a way that it is used for an electronic control box and/or for an assembly kit according to the present disclosure.

### BRIEF DESCRIPTION OF THE DRAWINGS

Further advantages, features, and objects of the invention will be apparent from the following detailed description of the invention in connection with the associated drawings, wherein the drawings show:

FIG. 1: a possible embodiment of an electronic control box in a schematic perspective explosion view;

FIG. 2A: the lower part of an electronic control box according to FIG. 1 in a first modification for a first housing height;

FIG. 2B: the lower part of an electronic control box according to FIG. 1 in a second modification for a second housing height;

FIG. 2C: the lower part of an electronic control box according to FIG. 1 in a third modification for a third housing height;

FIG. 3: a detailed view of a rigid information transmitting device in a schematic, perspective view.

### DETAILED DESCRIPTION

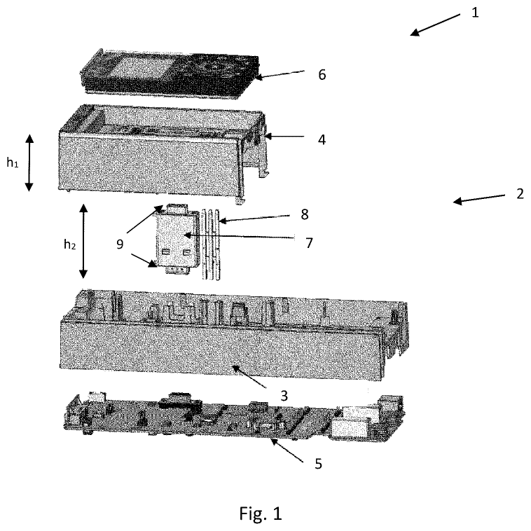

FIG. 1 shows an electronic control box 1 in a schematic, perspective explosion view. In this view, the various components and their arrangement relative to each other can be seen particularly well. It is to be noted that the electronic control box 1 that is shown in FIG. 1 shows only an exemplary possible embodiment of an electronic control box 1 according to the present disclosure.

Electronic control box 1 comprises a housing 2 that essentially comprises two parts 3, 4, namely a lower first part 2 and upper second part 4. Presently, the upper second part 4 shows a shorter length (axial direction), as compared to the lower first part 3 of the housing 2, so that an additional cover (not shown) might be used for covering the respective section of the upper surface of the first part 3 of housing 2.

Further, an electronic control unit 5 that is presently designed as a printed circuit board is arranged in the lower section of first part 3 of housing 2 of electronic control box 1. Presently, the electronic control unit 5 forms part of the bottom wall of first part 3 of housing 2. However, a design in which the electronic control unit 5 is contained inside of the housing 2/first part 3 of housing 2 is possible as well.

On the upper, second part 4 of housing 2, a human control interface 6 is placed that is presently designed as a control panel. As an example, this attachment may be realised by clamping means. The control panel 6 can be of a standard design, as it is readily available on the market.

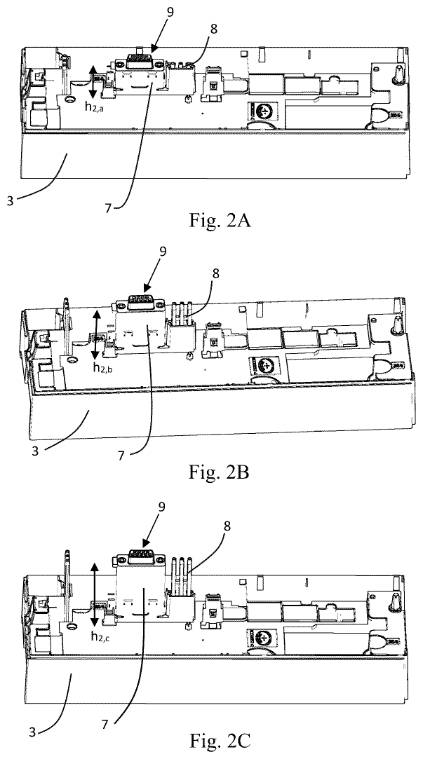

As indicated in FIG. 1, the height h₁ of second part 4 of housing 2 may be variable. As an example, a basic height h_{1,0} (as shown in FIG. 1; compare FIG. 2A) may be chosen. This basic height h_{1,0} may be varied to a different height. Preferably, a certain discrete multiplication scheme might be chosen, like h_{1,a}=1*h_{1,0} (FIG. 2A), h_{1,b}=1.5*h_{1,0} (FIG. 2B) and h_{1,c}=2*h_{1,0} (FIG. 2C). However, different multiplicative factors may be chosen as well, depending on the circumstances. In particular, those circumstances may be due to the machinery, in which the electronic control box 1 is used.

A different height might be required due to a preferred design of the electronic control unit 5, in which the electronic control unit 5 might comprise two parts, where one of those two parts (not shown) might be interchangeable and connected to the first part using a plug-in connector. The exchangeable part might show a different height due to different requirements, resulting in a necessity to provide a housing 2 (or parts thereof 3, 4) with a different height.

As can be seen in FIG. 1, the electrical 7 and optical 8 connection of signals is realised using an electrical rigid information transmitting device 7 (electrical information) and an optical rigid information transmitting device 8 (optical signals). Presently, the electrical rigid information transmitting device 7 is designed separately from the optical rigid information transmitting device 8.

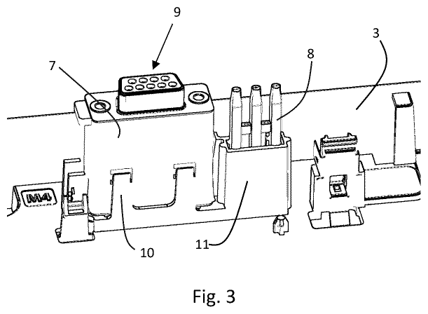

Indeed, the electrical rigid information transmitting device 7 comprises a plurality of several electrical conductors (see also FIGS. 2A-2C and 3). The electrical connection with the electronic control unit 5 and the control panel 6 is presently realised by a plug-in connection, which is presently realised as a standard D-sub connector.

The optical information is transmitted by presently three distinct optical rigid information transmitting devices 8 that are presently designed as three light guides that are made of a transparent plastics material.

The optical rigid information transmitting devices 8 transmit information that are generated by a plurality of LEDs that are soldered onto the electronic controller unit 5 towards control panel 6, so that they are visible in a top view by a user of the machinery.

In FIGS. 2A-2C three distinct variations of the first part 3 (lower part) of the housing 2 is shown, together with appropriate variations of electrical rigid information transmitting devices 7 and optical rigid information transmitting devices 8. Namely, the heights h₂ of the respective rigid information transmitting devices 7, 8 are varied to correspond to a housing 2 with a different height h₁, and therefore to a different distance between electronic control unit 5 and control panel 6. Possible heights were already mentioned above. However, it should be stressed again, that the given numbers only exemplary, and different numbers could be used as well. Further, it should be stressed that a “corresponding length of the rigid information transmitting device 7, 8 with respect to the height of the housing 2” does not necessarily imply that h_{2,a}=1*h_{2,0}, h_{2,b1}=1.5*h_{2,0} an/or h_{2,c1}=2*h_{2,0}, if h_{1,a}=1*h_{1,0}, h_{1b}=1.5*h_{1,0} and h_{1,c}=2*h_{1,0} holes. This is because the sizes of plugs/sockets, the exact positioning of electronic controller unit 5 and human control interface 6 and the like have to be considered.

In FIG. 3, there is finally a detailed view onto the electrical rigid information transmitting device 7 and the—presently three—optical rigid information transmitting devices 8.

The respective devices 7, 8 are held in position by appropriately designed guide supports 10, 11, namely a guide support 10 that is provided for the electrical rigid information transmitting device 7 and a guide support 11 for the optical rigid information transmitting devices 8.

It is to be noted that a single one or a plurality of the features of one, several or all of the presently disclosed detailed embodiments may be used in combination with the generic description of the present disclosure.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. An electronic control box, in particular electronic control box for a motor drive arrangement, comprising a housing with at least a first part and a second part, an electronic controller unit and at least one human control interface, wherein the electronic controller unit is mounted in the first part of the housing and the human control interface is arranged in at least one section of the second part of the housing, wherein at least one rigid information transmitting device that is designed and arranged to transmit a signal, in particular an optical and/or an electrical signal, between the electronic controller unit and the human control interface, wherein the at least one rigid information transmitting device is placed between the electronic controller unit and the human control interface, and that is separate from the electronic controller unit and the human control interface.

2. The electronic control box according to claim 1, wherein at least one of the rigid information transmitting devices comprises at least two, preferably a plurality of conduits, preferably, at least in part, of the same signal type and/or of a different signal type.

3. The electronic control box according to claim 1, wherein at least one of the rigid information transmitting devices is designed and arranged as an electrical connector and/or as an optical conduit device.

4. The electronic control box according to claim 1, wherein the rigid information transmitting device is designed and arranged as a plug-in connector device, preferably at least in part and/or at least on one of its sides.

5. The electronic control box according to claim 1, wherein the first part of the housing comprises a bottom surface wall and/or the second part of the housing comprises a top surface wall and/or at least one of the parts of the housing comprises a side wall and/or the housing comprises a third part that is designed and arranged as a side wall and/or wherein the distance (h₂) between the electronic controller unit and at least one human controller interface can be varied, preferably in steps.

6. The electronic control box according to claim 1, wherein the electronic controller unit comprises a plurality of sub-units and/or in that the electronic controller unit is designed, at least in part, as a printed circuit board.

7. The electronic control box according to claim 1, wherein at least one human control interface is taken from the group, comprising optical indicators, buttons, touch areas, electronic displays, light-emitting areas, and control panels.

8. An assembly kit, comprising at least one electronic control box according to claim 1, wherein at least two housing parts that result in a different distance (h₂) between the electronic controller unit and the human control interface, wherein preferably the at least two housing parts yield a different height (h₁) of the side walls of the housing, and at least two rigid information transmitting devices with a different length (h₂) are provided, wherein the lengths (h₂) of the rigid information transmitting devices correspond to the different distances between the electronic controller unit and the the human control interface.

9. A method of arranging an electronic controller unit, in particular an electronic controller unit for a motor drive arrangement, and a human control interface at a different distance (h₂), preferably in connection with a housing, wherein the signal connection, in particular an electrical signal connection and/or an optical signal connection between the electronic controller unit and the human control interface is effectuated by at least one rigid information transmitting device.

10. The method according to claim 9, wherein it is employed for an electronic control box for a motor drive arrangement, comprising a housing with at least a first part and a second part, an electronic controller unit and at least one human control interface, wherein the electronic controller unit is mounted in the first part of the housing and the human control interface is arranged in at least one section of the second part of the housing, wherein at least one rigid information transmitting device that is designed and arranged to transmit a signal, in particular an optical and/or an electrical signal, between the electronic controller unit and the human control interface, wherein the at least one rigid information transmitting device is placed between the electronic controller unit and the human control interface, and that is separate from the electronic controller unit and the human control interface.
